(19) United States
(12) Patent Application Publication
(10) Pub. No.: US 2014/0290563 A1
(43) Pub. Date: Oct. 2, 2014

(54) METHOD OF MANUFACTURING SINGLE CRYTSAL INGOT, AND SINGLE CRYSTAL INGOT AND WAFER MANUFACTURED THEREBY

(71) Applicants: Yun-Seon Jang, Gumi-si (KR); Young-Ho Hong, Seocho-gu (KR); Yo-Han Jung, St. Louis, MO (US); Se-Hun Kim, Gumi-si (KR)

(72) Inventors: Yun-Seon Jang, Gumi-si (KR); Young-Ho Hong, Seocho-gu (KR); Yo-Han Jung, St. Louis, MO (US); Se-Hun Kim, Gumi-si (KR)

(21) Appl. No.: 13/822,841

(22) PCT Filed: Jul. 3, 2012
(86) PCT No.: PCT/KR2012/005286

§ 371 Date: Apr. 7, 2014

(30) Foreign Application Priority Data
Jul. 6, 2011 (KR) 10-2011-0067040

(51) Int. Cl. C30B 15/20; G01N 25/72

(52) U.S. Cl. CPC C30B 15/20; G01N 25/72
USPC 117/15; 73/866

(57) ABSTRACT

Provided is a method of evaluating quality of a wafer or a single crystal ingot and a method of controlling quality of a single crystal ingot by using the same. The method of evaluating quality of a wafer or a single crystal ingot according to an embodiment may include performing Cu (copper) haze evaluation on a wafer or a slice of a single crystal ingot and Cu haze scoring with respect to the result of the Cu haze evaluation.

### CROSS-REFERENCE TO RELATED APPLICATIONS

The present application is a national phase application of P.C.T. application PCT/KR2012/005286 filed Jul. 3, 2012, which claims the priority benefit of Korean patent application 10-2011-0067040 filed Jul. 6, 2011, the disclosures of which are incorporated herein by reference.

### BACKGROUND OF THE INVENTION

1. Field of the Invention

The present disclosure relates to a method of evaluating quality of a wafer or single crystal ingot and a method of controlling quality of a single crystal ingot by using the same.

2. Description of the Related Art

In general, a Czochralski (hereinafter, referred to as “CZ”) method has been widely used as a method of manufacturing a silicon wafer. In the CZ method, polycrystalline silicon is charged into a quartz crucible, and heated and melted by a graphite heating element. Then, a seed crystal is immersed in a silicon melt formed by melting and crystallization is allowed to occur at an interface. A single crystal silicon ingot is grown by pulling as well as rotating the seed crystal. Thereafter, a wafer form is prepared by slicing, etching, and polishing the silicon ingot.

A single crystal silicon ingot or silicon wafer manufactured by using the foregoing method has crystal defects such as crystal originated particles (COP), flow pattern defect (FPD), oxygen induced stacking fault (OISF), and bulk micro defect (BMD). Decreases in density and size of such grown-in defects are required and it has been confirmed that the crystal defects affect device yield and quality. Therefore, a technique removing crystal defects as well as easily and quickly evaluating such defects is important.

Also, according to crystal growing conditions, a single crystal silicon ingot or silicon wafer includes a V-rich region having defects formed by agglomeration of vacancies saturated due to dominant vacancy-type point defects, a Pv region having dominant vacancy-type point defects but without agglomerated defects, a vacancy/interstitial (V/I) boundary, a Pi region having dominant interstitial point defects but without agglomerated defects, and a I-rich region having defects formed by agglomeration of interstitial silicon saturated due to dominant interstitial point defects.

In terms of evaluating a level of crystal quality, it is important to identify positions in which such defect regions are generated and how such defect regions are changed for a crystal length of the single crystal ingot.

According to the related art, in a single crystal ingot prepared by the CZ method, a V-rich region having void defects is generated when the ingot is grown at a critical value of V/G or more (high-speed growth) according to a Voronkov theory referred to as “V/G”, oxidation induced stacking fault (OISF) defects are generated in a ring shape at an edge or center region when the ingot is grown at the critical value of V/G or less (low-speed growth), and the I-rich region, a loop dominant point defect (LDP) zone, is generated by entangled dislocation loops having interstitial silicon gathered therein when the ingot is grown at a lower speed.

A defect-free region, which is neither V-rich nor I-rich, exists at a boundary between the V-rich region and the I-rich region. The defect-free region is also categorized into a Pv region, a vacancy dominant point defect (VDP)-free zone, and a Pi region, an interstitial dominant point defect (IDP)-free zone, and is considered as a margin prepared in order to manufacture a defect-free wafer.

FIG. 1 is an exemplary view illustrating control of a pulling speed according to the related art and shows experimental examples (case 1 and case 2) for setting a target pulling speed during single crystal growth.

Control of crystal defects introduced during single crystal growth is very important in order to reduce a circuit line width for high integration according to Moore's law. A typical method of preparing a defect-free single crystal wafer is performed by setting a target after a pulling speed of a defect-free region is identified by performing a vertical analysis on a corresponding region through V-test and N-test, in which a pulling speed is artificially adjusted to identify a defect-free margin as shown in FIG. 1.

Also, according to the related art, there have been attempts to design an upper hot zone (HZ) in order to manufacture a defect-free single crystal, for example, adjusting G value and ΔG (temperature gradient in a radial direction) of a crystal so as to correspond to a defect-forming temperature range through various shapes of an upper insulator, maximizing an efficiency of a heat accumulation space by adjusting a gap from a melt surface to the upper HZ, and controlling Si melt convection or a heat transfer path through a relative position from a maximum heat-generating portion of a heater to the melt surface. Alternatively, optimization of process parameters has been attempted, such as controlling an argon (Ar) flow rate, controlling a ratio of seed rotation speed to crucible rotation speed (SR/CR), or application of various types of magnetic fields.

However, with respect to the related art, optimization of the defect-free margin in manufacturing a defect-free single crystal may be difficult.

For example, the V test or N test may identify some regions of a body section in one batch and since manufacturing of a Si single crystal by using the CZ method is generally a continuous growing process, a difference in thermal history in crystal cooling according to an ingot length is generated even in the case that same HZ and process parameters are used. Also, a defect-free target pulling speed may be affected according to an increase in a crystal length due to changes in a Si melt volume according to crystal growth.

Further, according to the related art, costs due to quality loss may occur in the manufacturing of a defect-free single crystal.

For example, loss may be generated due to an increase in a quality rejection rate in a prime range, because setting of the target pulling speed is inaccurate, and the tests as in FIG. 1 may be performed in many times in order to identify the defect-free target pulling speed for a length.

However, since the target pulling speed does not cause changes in thermal history in crystal cooling according to the rapid changes in the pulling speed as in FIG. 1, the target value may be changed due to a difference in real thermal history between a quality margin identified in the V test or N test and a set value of the target pulling speed.

Also, as shown in FIG. 1, it is most important to set an accurate target pulling speed in order to grow a defect-free single crystal growth according to the related art during growth of a large diameter, heavy single crystal having a diameter of 300 mm or more. However, as described above, a typical defect-free region changes for the ingot length. Therefore, losses in quality, cost, and time may occur, because errors may occur due to the generation of the difference in thermal history of crystal inevitably generated during setting the target puling rate after the V test or N test or additional tests for identifying a margin for a length may be continuously repeated.

### SUMMARY OF THE PRESENT INVENTION

### Technical Problem

Embodiments provide a method of evaluating quality of a wafer or single crystal ingot, which is able to perform quality prediction and precision control through scoring with respect to an entire prime range by establishing a model using a copper (Cu) haze evaluation method in growing a high-quality silicon (Si) single crystal and preparing quantitative criteria in setting a target pulling speed, and a method of controlling quality of a single crystal ingot by using the foregoing method.

### Solution to Problem

In one embodiment, a method of evaluating quality of a wafer or single crystal ingot includes: performing Cu (copper) haze evaluation on a wafer or a slice of a single crystal ingot; and Cu haze scoring with respect to a result of the Cu haze evaluation.

In another embodiment, a method of controlling quality of a single crystal ingot includes: performing Cu haze evaluation on a wafer or a slice of a single crystal ingot; Cu haze scoring with respect to a result of the Cu haze evaluation; and tuning a target pulling speed based on a value of the result of the Cu haze scoring evaluation.

### Advantageous Effects of Invention

According to a method of evaluating quality of a wafer or single crystal ingot according to an embodiment and a method of controlling quality of a single crystal ingot by using the method, quality prediction and precision control through scoring with respect to an entire prime range may be possible by establishing a model using a copper (Cu) haze evaluation method in growing a high-quality silicon (Si) single crystal and preparing quantitative criteria in setting a target pulling speed.

For example, according to the embodiment, since scoring may be possible through a Cu haze evaluation method during growing of a defect-free single crystal by Cu haze modeling, a corresponding region may be distinguished through a Cu haze map generated during quality evaluation by providing a score for each crystal region, and thus, an accurate target pulling speed in a next batch may be set by adjusting a pulling speed scored with respect to a region distinguished by a map for a prime region.

Also, according to the embodiment, identification of crystal regions at center and edge portions of a single crystal may be possible and thus, may become application criteria during fine tuning of process parameters.

According to the embodiment, an accurate target pulling speed may be set without repeated V test and N test in setting a target pulling speed for growing a high-quality Si single crystal and may be immediately applicable to a single crystal growing process.

According to the embodiment, accurate data with respect to a real defect-free margin region may be secured for an entire prime range through adjustment values in a score range and a quality margin, and thus, costs due to quality deterioration may be minimized and a uniform high-quality Si single crystal may be manufactured in a minimum time in addition to an increase in productivity.

Also, the embodiment may be entirely applied to a small to large diameter.

Further, according to the embodiment, more accurate judgment and quality achievement may be possible by segmentation of a crystal region, e.g., separately specifying scores for Pv and Pi.

### BRIEF DESCRIPTION OF THE DRAWINGS

FIG. 1 is an exemplary view illustrating control of a pulling speed according to the related art.

FIG. 2 is a schematic view illustrating a method of evaluating quality of a wafer or single crystal ingot according to an embodiment and a method of controlling quality of a single crystal ingot by using the same.

FIG. 3 is an exemplary view illustrating a method of calculating Cu haze scores for a sample in the method of evaluating quality of a wafer or single crystal ingot according to the embodiment and the method of controlling quality of a single crystal ingot by using the same.

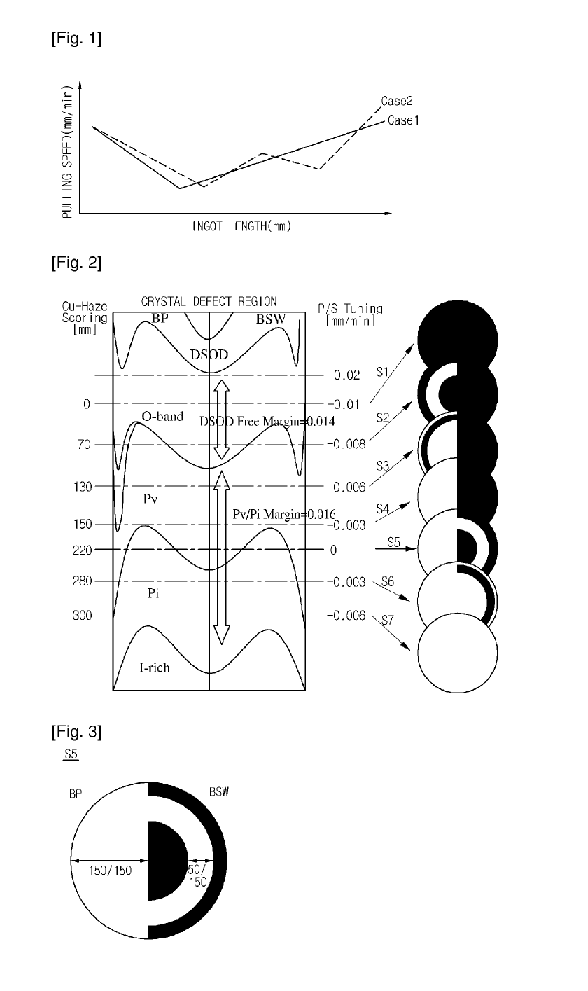

### DETAILED DESCRIPTION

In the description of embodiments, it will be understood that when a wafer, device, chuck, member, part, region, or surface is referred to as being ‘on’ another wafer, device, chuck, member, part, region, or surface, the terminology of ‘on’ and ‘under’ includes both the meanings of ‘directly’ and ‘indirectly’. Further, the reference about ‘on’ and ‘under’ each element will be made on the basis of drawings. In the drawings, the size of each element is exaggerated for convenience in description and the size of each element does not entirely reflect an actual size.

### Embodiment

FIG. 2 is a schematic view illustrating a method of evaluating quality of a wafer or single crystal ingot according to an embodiment and a method of controlling quality of a single crystal ingot by using the same.

The embodiment attempts to provide a method of evaluating quality of a wafer or single crystal ingot, which is able to perform quality prediction and precision control through scoring with respect to an entire prime range by establishing a model using a copper (Cu) haze evaluation method in growing a high-quality silicon (Si) single crystal and preparing quantitative criteria in setting a target pulling speed, and a method of controlling quality of a single crystal ingot by using the foregoing method.

For this purpose, the method of evaluating quality of a wafer or single crystal ingot according to the embodiment may include performing Cu haze evaluation on a wafer or a slice of a single crystal ingot and Cu haze scoring with respect to the result of the Cu haze evaluation.

According to the embodiment, since scoring through a Cu haze evaluation method may be possible during growing of a defect-free single crystal by Cu haze modeling, a corresponding region may be distinguished through a Cu haze map generated during quality evaluation by providing a score for each crystal region, and thus, an accurate target pulling speed in a next batch may be set by adjusting a pulling speed scored with respect to a region distinguished by a map for a prime region.

Also, according to the embodiment, identification of crystal regions at center and edge portions of a single crystal may be possible and thus, may become application criteria during fine tuning of process parameters.

According to the embodiment, the performing of the Cu haze evaluation may include performing a first heat treatment BP on some regions of the wafer or the slice of the single crystal ingot and performing a second heat treatment BSW on other regions of the wafer or the slice of the single crystal ingot.

For example, the first heat treatment may include performing an O-band heat treatment and the second heat treatment may include performing a Pv, Pi heat treatment.

In the embodiment, the Cu haze scoring method may perform Cu haze scoring through segmentation of defect regions of the wafer or the slice of the ingot.

For example, in the Cu haze scoring method, Cu haze scoring may be performed by specifying scores for a Pv region and a Pi region of the slice of the ingot.

According to the embodiment, more accurate judgment and quality achievement may be possible by segmentation of a crystal region, e.g., separately specifying scores for Pv and Pi.

Also, the Cu haze scoring in the embodiment may include establishing a Cu haze scoring map through the Cu haze evaluation.

According to the method of evaluating quality of a wafer or single crystal ingot according to the embodiment, quality prediction and precision control through scoring with respect to an entire prime range may be possible by establishing a model using a Cu haze evaluation method in growing a high-quality Si single crystal and preparing quantitative criteria in setting a target pulling speed.

The method of controlling quality of a single crystal ingot according to the embodiment may include performing a Cu haze evaluation on a wafer or a slice of a single crystal ingot, Cu haze scoring with respect to the result of the Cu haze evaluation, and tuning a target pulling speed based on a value of the result of the Cu haze scoring evaluation.

Contents of the performing of the Cu haze evaluation and the Cu haze scoring with respect to the result of the Cu haze evaluation may employ technical characteristics of the foregoing contents of the method of evaluating quality of a wafer or single crystal ingot.

The tuning of the target pulling speed in the embodiment may include preparing quantitative tuning criteria in setting the target pulling speed on the basis of the Cu haze scoring map after the establishing of the Cu haze scoring map through the Cu haze evaluation.

As a result, according to the embodiment, a target pulling speed in a next batch may be set by adjusting the pulling speed scored according to the tuning criteria for each crystal region of the single crystal ingot on the basis of the Cu haze scoring map in the tuning of the target pulling speed.

According to the method of controlling quality of a single crystal ingot according to the embodiment, quality prediction and precision control through scoring with respect to an entire prime range may be possible by establishing a model using a Cu haze evaluation method in growing a high-quality Si single crystal and preparing quantitative criteria in setting a target pulling speed.

Also, according to the embodiment, an accurate target pulling speed may be set without repeated V test and N test in setting a target pulling speed for growing a high-quality Si single crystal and may be immediately applicable to a single crystal growing process.

According to the embodiment, accurate data with respect to a real defect-free margin region may be secured for an entire prime range through adjustment values in a score range and a quality margin, and thus, costs due to quality deterioration may be minimized and a uniform high-quality Si single crystal may be manufactured in a minimum time in addition to an increase in productivity.

Further, the embodiment may be entirely applied to a small to large diameter.

Hereinafter, the method of evaluating quality of a wafer or single crystal ingot and the method of controlling quality of a single crystal ingot by using the same are described in more detail with reference to FIG. 2.

FIG. 2 is a schematic diagram for the embodiment illustrating a distribution of defects in a crystal according to changes in a pulling speed during growth of a defect-free single crystal.

For example, an O-band region, a Pv region, a Pi region, and a LDP region may be distinguished through a first heat treatment BP and a second heat treatment BSW by a Cu haze evaluation method.

The Cu haze evaluation method employed in the embodiment may be an evaluation method, in which one surface of a wafer or slice of Si single crystal is contaminated with high-concentration Cu by using a Cu-contaminated solution, a mixed solution of a buffered oxide etchant (BOE) solution and Cu, and a quick diffusion heat treatment is performed, and then crystal defect regions are distinguished by visually observing a contaminated surface or an opposite surface thereof under a spotlight. However, the embodiment is not limited thereto.

Examples of first sample to seventh sample (S1 to S7) on the right side of FIG. 2 show various types that may be presented as Cu haze scoring maps after a single crystal is grown at a predetermined target pulling speed.

For example, the first sample S1 having an entire black surface at the top presents inclination to an O-band region due to a high defect-free target pulling speed and shows that the O-band region becomes disappeared according to a decrease in a pulling speed (PS), e.g., a decrease of 0.01 mm/min.

Also, with respect to the fifth sample S5 located at third from the bottom, color of a left-half side of the entire wafer surface appears white and a single crystal grown for such a target shows that the 0-band has been controlled, and a right-half side of the entire wafer surface appears both black and white in which the black portion presents a Pv region and the white region presents a Pi region. Therefore, with respect to the fifth sample S5, it may be understood that a defect-free region in the wafer is formed, such as Pv-Pi-Pv.

Further, with respect to the seventh sample S7 at the bottom, it may be understood that a wafer having only a Pi region is manufactured when colors of both left and right side appear white.

In the embodiment, for example, scores in a range of 0 to 300 may be provided on the left side of FIG. 2 and segmentation of the scores may be adjusted.

When a product composed of Pv region and Pi region having the O-band controlled therein as a targeted quality is manufactured, a target score may be determined as 220.

For example, a target score may be determined within a range of 150 to 180 in FIG. 2. Herein, a free margin is determined and the free margin is divided by the score, and thus, a control rate of pulling speed for each score may be determined.

For example, with respect to FIG. 2, a target score of 220 is assumed as 0 having no control rate of pulling speed, and uniform quality in an entire prime range may be obtained by adjusting a target pulling rate with an adjustment value corresponding to a score in a corresponding Cu haze scoring map.

FIG. 3 is an exemplary view illustrating a method of calculating a Cu haze score for the fifth sample S5 in the method of evaluating quality of a wafer or single crystal ingot according to the embodiment and the method of controlling quality of a single crystal ingot by using the same.

FIG. 3 is a cross-sectional view, in which distribution of defects in a vertical direction in a 300 mm single crystal grown according to the embodiment is analyzed by a Cu haze evaluation method, and a method of assigning a score is as below, but the embodiment is not limited thereto.

First, an area of a white portion (the left-side of the wafer in FIG. 3) of a first heat treatment BP region according to the Cu haze evaluation method is measured. Then, an area of a white portion (the right-side of the wafer in FIG. 3) of a second heat treatment BSW region is measured and a score value is determined as a value obtained by adding areas of the white portions in the first heat treatment region and the second heat treatment region.

As another example, with respect to a second S2 sample map in the right-side of FIG. 2, both white portion and black portion exist in the map according to a BP evaluation method and in this case, regions of the white portion are added and the same method also applies to a BSW evaluation method.

In the embodiment, a score of 300 corresponds to a cross section of a 300 mm wafer, and a corresponding diameter may be used as it is according to each diameter and may be used by being proportionally adjusted for segmentation.

Table 1 is an example of quantitative tuning criteria in setting the target pulling speed on the basis of a Cu haze scoring map, as an example of adjustment of a target pulling speed in the method of evaluating quality of a wafer or single crystal ingot according to the embodiment and the method of controlling quality of a single crystal ingot by using the same. However, the embodiment is not limited thereto.

TABLE 1

| Cu haze scoring for | Margin contrast [%] |
|---|---|
| crystal region [mm] | Pulling speed (PS) tuning method |
| 0 | Margin * −63% |
| 70 | Margin * −50% |
| 130 | Margin * −38% |
| 150 | Margin * −19% |
| 220 | Margin * 0% |
| 280 | Margin * 19% |
| 300 | Margin * 38% |

Also, according to the embodiment, identification of crystal defect regions in a prime range is quantitatively performed through the map of the Cu haze evaluation method to become criteria during optimization of parameters. For example, when the maps of the right-side of FIG. 2 in a prime range are presented by being variously mixed one another, a targeted quality may be obtained through fine tuning of levels of parameters used for each range.

TABLE 2

| Pulling | | | |
|---|---|---|---|
| speed (PS) | | | |
| for each | | Pull speed tuning | New target |
| position | Cu haze score | [%] | pulling speed |
| A | 0 | −80 to 63% | A + (Margin * |
| | | | −(80 to 63)%) |
| B | 0 < Score ≦ 50 | −62.8 to 53.8% | B + (Margin * |
| | | | −(62.8 to 53.8)%) |
| C | 50 < Score ≦ 150 | −53.6 to 48.3% | C + (Margin * |
| | | | −(53.6 to 48.3)%) |
| D | 100 < Score ≦ 150 | −48.2 to 19% | D + (Margin * |
| | | | −(48.2 to 19)%) |
| E | 150 < Score ≦ 220 | −18.2 to 0% | E + (Margin * |
| | | | −(18.2 to 0)%) |
| F | 220 < Score ≦ 250 | +0.3 to 5.8% | F + (Margin * |
| | | | (0.3 to 5.8)%) |
| G | 250 < Score ≦ 300 | +6 to 38% | G + (Margin * |
| | | | (6 to 38)%) |

Table 2 is an example of calculating a target pulling speed to be used for a next batch by adjusting the pulling speed with a pulling speed (PS) for a position of the ingot and a tuning value of the target pulling speed corresponding to a score according to the Cu haze score for the position of the ingot by applying the method of evaluating quality of a wafer or single crystal ingot according to the embodiment and the method of controlling quality of a single crystal ingot by using the same. However, the embodiment is not limited thereto.

In the embodiment, the target pulling speed may be a value in which margin contrast % is added to a corresponding pulling speed (PS). At this time, the margin may be in a range of about 0.1 mm/min to about 0.5 mm/min, but the embodiment is not limited thereto.

Tables 1 and 2 are examples in which the embodiment is used, but the present invention is not limited thereto.

Uniform quality may be obtained with respect to an entire prime region according to the result obtained after the score method by the Cu haze scoring map is used in growing a real Si single crystal based on the method of evaluating quality of a wafer or single crystal ingot according to the embodiment and the method of controlling quality of a single crystal ingot by using the same.

According to the embodiment, the number of unlimited repetitive tests performed for identifying a margin through a typical V test or N test or changes in a defect-free margin for a length of crystal are innovatively decreased. Since quantification may be possible after scores are calculated based on the result of a minimum V test or N test, accurate quality prediction may be not only possible but a decrease in quality cost and an improvement in productivity may also be possible by establishing a clear model for setting a target pulling speed.

Also, the embodiment may be modified according to changes in the structure or shape of the hot zone (HZ). For example, when the defect-free margin is changed according to the changes in the HZ structure, magnetic field, and process parameters, changes in an adjustment value corresponding to a score may be possible. Further, as another example, a score value itself may be used for each diameter, such as 150 mm, 200 mm, 300 mm, and 450 mm, and may be adjusted at an appropriate ratio for segmentation.

According to the method of evaluating quality of a wafer or single crystal ingot according to the embodiment and the method of controlling quality of a single crystal ingot by using the same, quality prediction and precision control through scoring with respect to an entire prime range may be possible by establishing a model using a copper (Cu) haze evaluation method in growing a high-quality silicon (Si) single crystal and preparing quantitative criteria in setting a target pulling speed.

For example, according to the embodiment, since scoring may be possible through a Cu haze evaluation method during growing of defect-free single crystal by Cu haze modeling, a corresponding region may be distinguished through a Cu haze map generated during quality evaluation by providing a score for each crystal region, and thus, an accurate target pulling speed in a next batch may be set by adjusting a pulling speed scored with respect to a region distinguished by a map for a prime region.

Also, according to the embodiment, identification of crystal regions at center and edge portions of a single crystal may be possible and thus, may become application criteria during fine tuning of process parameters.

According to the embodiment, an accurate target pulling speed may be set without repeated V test and N test in setting a target pulling speed for growing a high-quality Si single crystal and may be immediately applicable to a single crystal growing process.

According to the embodiment, accurate data with respect to a real defect-free margin region may be secured for an entire prime range through adjustment values in a score range and a quality margin and thus, costs due to quality deterioration may be minimized and a uniform high-quality Si single crystal may be manufactured in a minimum time in addition to an increase in productivity.

Also, the embodiment may be entirely applied to a small to large diameter.

Further, according to the embodiment, more accurate judgment and quality achievement may be possible by segmentation of a crystal region, e.g., separately specifying scores for Pv and Pi.

The characteristics, structures, and effects described above are included in at least one embodiment and are not limited to only one embodiment. Furthermore, it will be understood by those of ordinary skill in the art that various changes in form and details may be made therein without departing from the spirit and scope of the present invention as defined by the following claims.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

Since quality evaluation of a wafer or single crystal ingot may be performed according to the present invention and the quality of the single crystal ingot may be controlled by using the quality evaluation, the present invention has industrial applicability.

What is claimed is:

1. A method of evaluating quality of a wafer or single crystal ingot, the method comprising:
performing Cu (copper) haze evaluation on a wafer or a slice of a single crystal ingot; and
Cu haze scoring with respect to a result of the Cu haze evaluation.

2. The method according to claim 1, wherein the performing of the Cu haze evaluation comprises:
performing a first heat treatment on some regions of the wafer or the slice of the single crystal ingot; and
performing a second heat treatment on other regions of the wafer or the slice of the single crystal ingot.

3. The method according to claim 2, wherein the first heat treatment comprises performing an O-band heat treatment and the second heat treatment comprises performing a PV, Pi heat treatment.

4. The method according to claim 1, wherein in the Cu haze scoring, a method of the Cu haze scoring comprises performing Cu haze scoring through segmentation of defect regions of the wafer or the slice of the ingot.

5. The method according to claim 4, wherein the method of the Cu haze scoring comprises performing Cu haze scoring by specifying scores of a Pv region and a Pi region of the wafer or the slice of the ingot.

6. The method according to claim 3, wherein the Cu haze scoring comprises:
measuring an area of a first Pi region with respect to an O-band heat treated region by the Cu haze evaluation method;
measuring an area of a second Pi region with respect to a Pv, Pi heat treated region; and
adding the area of the first Pi region and the area of the second Pi region to set as a Cu haze score value.

7. The method according to claim 1, wherein the Cu haze scoring comprises establishing a Cu haze scoring map through the Cu haze evaluation.

8. A method of controlling quality of a single crystal ingot, the method comprising:
performing Cu (copper) haze evaluation on a wafer or a slice of a single crystal ingot;
Cu haze scoring with respect to a result of the Cu haze evaluation; and
tuning a target pulling speed based on a value of the result of the Cu haze scoring evaluation.

9. The method according to claim 8, wherein the tuning of the target pulling speed comprises:
establishing a Cu haze scoring map through the Cu haze evaluation; and
preparing quantitative tuning criteria in setting the target pulling speed based on the Cu haze scoring map.

10. The method according to claim 9, wherein the tuning of the target pulling speed comprises setting a target pulling speed in a next batch by adjusting the scored pulling speed according to the tuning criteria for each crystal region of the single crystal ingot based on the Cu haze scoring map.

11. The method according to claim 8, wherein the Cu haze scoring uses the method of evaluating quality of a single crystal ingot of any one of claims 4 to 7.
